(19) United States
(12) Patent Application Publication
(10) Pub. No.: US 2025/0258444 A1
(43) Pub. Date: Aug. 14, 2025

(54) OPTICAL SYSTEM, AND METHOD FOR OPERATING AN OPTICAL SYSTEM

(71) Applicant: Carl Zeiss SMT GmbH, Oberkochen (DE)

(72) Inventors: Andreas RABA, Niederschoenenfeld (DE); Hans Michael STIEPAN, Aalen (DE); Johannes LIPPERT, Buch am Wald (DE); Markus RAAB, Schillingsfuerst (DE); Axel WITT, Rheinstetten (DE)

(21) Appl. No.: 19/196,264

(22) Filed: May 1, 2025

Related U.S. Application Data
(63) Continuation of application No. PCT/EP2023/075903, filed on Sep. 20, 2023.

(30) Foreign Application Priority Data
Nov. 4, 2022 (DE) 10 2022 211 636.4

(51) Int. Cl. G03F 7/00; G02B 7/18; H05B 3/84

(52) U.S. Cl. CPC G03F 7/70891; G03F 7/70091; G03F 7/70141; G03F 7/7015; G03F 7/70525; H05B 3/84; G02B 7/1815; H05B 2203/007

(57) ABSTRACT

An optical system, such as in a microlithographic projection exposure apparatus, comprising at least one optical element and a heating device for heating the optical element. The heating device comprises a plurality of heating segments to which electric current can be applied in order to generate heat. A continuous thermally induced deformation profile of the optical active surface having a deformation amplitude of at least 1λ can be adjusted by the heating segments so that the integral of the Fourier decomposition over at least one decadic spatial wavelength range is less than 10 mλ.

### CROSS-REFERENCE TO RELATED APPLICATIONS

The present application is a continuation of, and claims benefit under 35 USC 120 to, international application No. PCT/EP2023/075903, filed Sep. 20, 2023, which claims benefit under 35 USC 119 of German Application No. 10 2022 211 636.4, filed Nov. 4, 2022. The entire disclosure of each of these applications is incorporated by reference herein.

### FIELD

The disclosure relates to an optical system and to a method for operating an optical system, such as in a microlithographic projection exposure apparatus.

### BACKGROUND

Microlithography is used for producing microstructured components, such as integrated circuits or LCDs. The microlithography process is performed in what is known as a projection exposure apparatus comprising an illumination device and a projection lens. The image of a mask (=reticle) illuminated via the illumination device is in this case projected via the projection lens onto a substrate (e.g. a silicon wafer) coated with a light-sensitive layer (photoresist) and arranged in the image plane of the projection lens, in order to transfer the mask structure to the light-sensitive coating on the substrate.

In projection lenses designed for the EUV range, for example, at wavelengths of for example approximately 13 nanometers (nm) or approximately 7 nm, mirrors are used as optical components for the imaging process owing to the general lack of availability of suitable light-transmissive refractive materials.

An issue which can arise in practice is that, inter alia as a result of absorption of the radiation emitted by the EUV light source, the EUV mirrors can heat up and undergo an associated thermal expansion or surface deformation, which can in turn result in an impairment of the imaging properties of the optical system. Various approaches are known for avoiding such surface deformations and associated optical aberrations.

It is known inter alia to use a material with ultra-low thermal expansion (“Ultra-Low Expansion Material”), for example a titanium silicate glass sold by Corning Inc. under the name ULE™, as the mirror substrate material and to set what is known as the zero-crossing temperature in a region near the optical effective surface. At this zero-crossing temperature, which is approximately ∂=30° C. for example for ULE™, the coefficient of thermal expansion has in its temperature dependence a zero crossing in the vicinity of which no thermal expansion or only negligible thermal expansion of the mirror substrate material takes place. A further approach for avoiding surface deformations caused by heat inputs into an EUV mirror includes active direct cooling by way of cooling channels which are formed in the mirror substrate and through which a cooling fluid can flow.

A further known approach includes indirect heating using a heating device, for example on the basis of infrared radiation or with resistive heating elements to which electrical current can be applied. By way of such a heating device, active mirror heating can be effected in phases of comparatively low absorption of EUV used radiation, the active mirror heating being correspondingly decreased as the absorption of the EUV used radiation increases.

In practice, a further issue that can occur is that an EUV mirror is exposed to changing intensities of the incident electromagnetic radiation also from a spatial point of view during the operation of the microlithographic projection exposure apparatus, for example on account of the use of illumination settings with an intensity that varies over the optical effective surface of the respective EUV mirror.

Taking account of such scenarios can be a demanding challenge in practice insofar as, for instance with radiation-based heating, thermalization might be possible only with relatively greatly limited spatial resolution and can additionally lead to undesired incoupling of stray light into the respective optical system. By contrast, the use of resistance heating can enable higher spatial resolutions, but the deformation profile ultimately set by way of the thermalization when heating separate sectors can have undesired steps which can impair the compensation or correction action that is ultimately set and thus the optical properties of the respective optical system.

Reference is made merely by way of example to WO 2018/177649 A1 and DE 10 2017 207 862 A1.

### SUMMARY

The present disclosure seeks to provide an optical system and a method for operating an optical system, such as in a microlithographic projection exposure apparatus, which enable effective avoidance of surface deformations caused by heat inputs into the optical element and associated optical aberrations.

In an aspect, the disclosure provides an optical system according, such as in a microlithographic projection exposure apparatus, which has a predefined operating wavelength λ, comprises
at least one optical element which has an optical effective surface; and
a heating device for heating this optical element, wherein the heating device has a plurality of heating segments to which electrical current can be applied to generate heat;
wherein the heating segments can be used to set a continuous thermally induced deformation profile of the optical effective surface with a deformation amplitude of at least 1λ in such a way that the integral of the Fourier analysis over at least one decadic spatial wavelength range is less than 10 mλ.

Generating a heating profile may be effected for example to avoid a deformation of the optical effective surface of the optical element that ultimately occurs during operation of the optical system. However, in a further application, the generation of the heating profile may also be effected with the aim of active manipulation, i.e. targeted deformation of the optical effective surface in the context of an actuation (for example for correcting aberrations brought about elsewhere in the optical system).

The disclosure involves the concept of realizing, proceeding from the use of an electrical heating device, comparatively smoother gradients in the heating profile that is ultimately set, by avoiding undesired sharp transitions or edges between different heating zones. In this case, the realization of such a comparatively smooth gradient, as described below on the basis of various embodiments, can be effected in different ways.

Here, according to the disclosure, the integral of the Fourier analysis of the set deformation profile can be used as a measure for the waviness of this deformation profile.

For example in the spatial wavelength range from 0.1 millimeter (mm) to 1 mm, this may be a measure for the stray light caused in the system, which can have an undesirable effect on the performance of the optical system. According to the disclosure, a deformation profile with a significant stroke of at least 1 2 is settable, wherein the integral of the Fourier analysis of the set deformation profile in a decadic spatial wavelength range (for example from 0.1 mm to 1 mm) is less than 10 mλ.

In embodiments of the disclosure, the heating device is designed such that at least two heating zones generated by different heating segments have a sufficiently large overlap. Here, the disclosure includes the concept of preventing the formation of undesired step profiles by using the heating device according to the disclosure to generate heating zones which overlap one another significantly in certain parts. In this case, the realization of such a sufficient overlap, as described below on the basis of various exemplary embodiments, can again be effected in different ways.

The realization according to the disclosure of heating profiles in an optical element on the basis of heating segments to which electrical current can be applied can be desirable in a number of ways in comparison to radiation-based heating (for example by way of IR emitters). On the one hand, according to the disclosure, the stray light effects that are generally associated with radiation-based heating systems can be avoided. Furthermore, with regard to the settable heating profiles, it is possible to achieve a significantly higher spatial resolution in comparison to radiation-based heating systems. The direct coupling, provided according to the disclosure in contrast to radiation-based heating, between the respective heating segments and the optical element to be heated also can make follow-up control for the case of a change in position (e.g. tilting) of the optical element in question superfluous.

A feature is that the heating segments according to the disclosure can simultaneously also be used as temperature sensors, with the result that closed control of the thermal state of the optical element in question and thus targeted detection and influencing of the temperature distribution or of the resultant thermally induced deformation of the optical element is enabled without additional design effort for the temperature measurement. For example, an illumination setting change effected during operation of the optical system can also be promptly identified and form the basis of a dynamic adaptation of the heating profile set according to the disclosure.

According to one embodiment, the continuous thermally induced deformation profile with a deformation amplitude of at least 1λ is settable in such a way that the integral of the Fourier analysis over at least one decadic spatial wavelength range is less than 5 mλ, such as is less than 3 mλ.

According to one embodiment, the at least one decadic spatial wavelength range comprises spatial wavelengths less than 100 micrometers (μm).

According to one embodiment, the at least one decadic spatial wavelength range comprises spatial wavelengths from 100 μm to 1 mm.

According to one embodiment, the at least one decadic spatial wavelength range comprises spatial wavelengths from 1 mm to 10 mm.

According to one embodiment, the operating wavelength is less than 250 nm, such as less than 200 nm.

According to one embodiment, the operating wavelength is less than 30 nm, such as less than 15 nm.

According to one embodiment, at least two heating zones generated by different heating segments partially overlap one another.

According to one embodiment, the heating segments are arranged in at least two planes which differ from one another and are at different distances from the optical effective surface.

According to one embodiment, the heating segments engage with one another in certain portions. The heating segments may for example together form an arrangement which is interleaved at least in certain regions.

According to one embodiment, the heating segments are in the form of electrical conductor tracks which, in order to obtain a locally varying heating capacity, form a branched arrangement and/or vary in terms of their width, their relative distance from one another or their material.

According to one embodiment, the heating segments are designed as layers or layer segments.

According to one embodiment, the heating segments are selectively actuatable independently of one another for the variable setting of different thermally induced deformation profiles in the optical element.

According to one embodiment, this selective actuation of the heating segments comprises transmission of actuation signals of different frequency to different heating segments by way of a common lead.

According to one embodiment, the optical system comprises a control device for varying a thermally induced deformation profile, generated by way of the heating device in the optical element, in dependence on an illumination setting set in the optical system.

According to one embodiment, the optical element is a mirror.

The disclosure also relates to a method for operating an optical system, such as in a microlithographic projection exposure apparatus, wherein the optical system has a predefined operating wavelength λ and comprises at least one optical element having an optical effective surface and a heating device for heating this optical element having a plurality of heating segments to which electrical current can be applied to generate heat, wherein the heating segments are used to set a continuous thermally induced deformation profile of the optical effective surface with a deformation amplitude of at least 1λ in such a way that the integral of the Fourier analysis over at least one decadic spatial wavelength range is less than 10 mλ.

According to one embodiment, a thermally induced deformation profile set by way of the heating segments is varied in dependence on an illumination setting set in the optical system.

According to one embodiment, the continuous thermally induced deformation profile is set in such a way that a deformation of the optical element which is associated with application of electromagnetic radiation to the optical element during operation of the optical system is at least partially compensated.

According to one embodiment, the continuous thermally induced deformation profile is set in such a way that an optical aberration which occurs during operation of the optical system is at least partially compensated.

The disclosure furthermore also relates to a method for operating an optical system, wherein the optical system comprises an optical element and a heating device for heating this optical element having a plurality of heating segments to which electrical current can be applied to generate heat, wherein a heating profile set by way of these heating segments is selected in dependence on an illumination setting used in the optical system. Here, the disclosure includes the concept of avoiding or at least reducing thermally induced deformations of an optical element (e.g. of a mirror) in an optical system by setting, in the optical element, a heating profile which is adapted to the illumination setting currently used during operation of the optical system. By way of example, if the illumination setting is a dipole setting with horizontally arranged illumination poles, the heating device according to the disclosure can be used to generate a heating profile, which is complementary to this illumination setting or the temperature distribution generated thereby in the optical element, on the optical effective surface on the optical element or mirror in order, as a result, to obtain a temperature distribution that is locally as homogeneous as possible in the optical element and to accordingly effectively avoid thermally induced deformations.

With respect to further refinements and features of the method, reference is made to the above statements in connection with the heating device according to the disclosure.

Further refinements of the disclosure can be gathered from the description and the dependent claims.

The disclosure will be explained in more detail below on the basis of exemplary embodiments illustrated in the appended figures.

### BRIEF DESCRIPTION OF THE DRAWINGS

In the figures:

FIG. 1 shows a schematic illustration of the possible structure of a microlithographic projection exposure apparatus designed for operation in the EUV;

FIGS. 2A-2B show schematic illustrations for explaining a possible embodiment of a heating device according to the disclosure with branched conductor tracks;

FIGS. 3-4 show schematic illustrations for explaining a possible saving according to the disclosure of cable leads;

FIGS. 5A-5B, 6A-6B, and 7 show schematic illustrations for explaining possible embodiments of a heating device according to the disclosure with use of a mediator layer of comparatively low electrical conductivity;

FIGS. 8A-8B show schematic illustrations for explaining possible embodiments of a heating device according to the disclosure on the basis of an inductive infeed of energy;

FIGS. 9 and 10A-10B show schematic illustrations for explaining possible realizations of a heating device according to the disclosure with overlapping heating zones;

FIG. 11 shows a schematic illustration for explaining a possible minimization of the number of channels or leads in a heating device according to the disclosure;

FIG. 12 shows a schematic illustration of a further embodiment of a heating device according to the disclosure;

FIGS. 13A-13D show schematic illustrations for explaining an additional temperature measurement that is possible in the case of a heating device according to the disclosure;

FIG. 14 shows a diagram for illustrating a Fourier analysis in a logarithmic plot of the spatial wavelength axis for an exemplary surface structure;

FIGS. 15A-15B-18A-18B show diagrams of different temperature profiles generated by individual heating segments, and the superposition thereof; and

FIG. 19 shows a diagram for illustrating the influence of lateral heat conduction on the overlap of the temperature profiles of adjacent heating segments.

### DETAILED DESCRIPTION

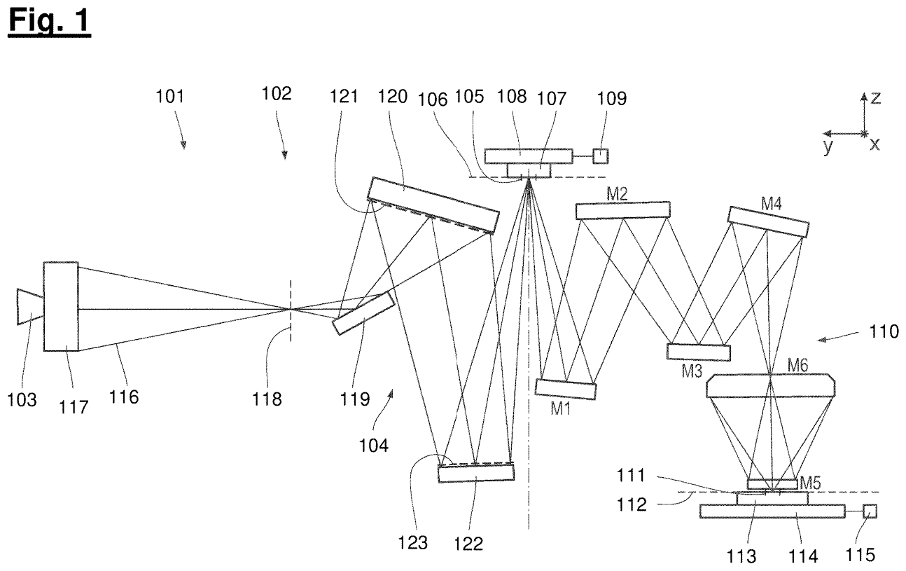

FIG. 1 schematically shows in meridional section the possible structure of a microlithographic projection exposure apparatus designed for operation in the EUV. The disclosure is not restricted to use in a projection exposure apparatus designed for operation in the EUV. For example, the disclosure can also be used in a projection exposure apparatus designed for operation in the DUV (i.e. at wavelengths less than 250 nm, such as less than 200 nm) or also in another optical system.

According to FIG. 1, the projection exposure apparatus 101 comprises an illumination device 102 and a projection lens 110. One embodiment of the illumination device 102 of the projection exposure apparatus 101 has, in addition to a light or radiation source 103, an illumination optical unit 104 for illuminating an object field 105 in an object plane 106. In an alternative embodiment, the light source 103 may also be provided as a module separate from the rest of the illumination device. In this case, the illumination device does not comprise the light source 103.

What is exposed here is a reticle 107 arranged in the object field 105. The reticle 107 is held by a reticle holder 108. The reticle holder 108 is displaceable by way of a reticle displacement drive 109, for example in a scanning direction. For explanatory purposes, a Cartesian xyz-coordinate system is depicted in FIG. 1. The x-direction runs perpendicularly to the plane of the drawing into the latter. The y-direction runs horizontally, and the z-direction runs vertically. The scanning direction runs along the y-direction in FIG. 1. The z-direction runs perpendicularly to the object plane 106.

The projection lens 110 serves for imaging the object field 105 into an image field 111 in an image plane 112. A structure on the reticle 107 is imaged onto a light-sensitive layer of a wafer 113 arranged in the region of the image field 111 in the image plane 112. The wafer 113 is held by a wafer holder 114. The wafer holder 114 is displaceable by way of a wafer displacement drive 115, for example along the y-direction. The displacement, firstly, of the reticle 107 by way of the reticle displacement drive 109 and, secondly, of the wafer 113 by way of the wafer displacement drive 115 may be synchronized with one another.

The radiation source 103 is an EUV radiation source. The radiation source 103 emits EUV radiation, which is also referred to below as used radiation or illumination radiation. For example, the used radiation has a wavelength in the range of between 5 nm and 30 nm. The radiation source 103 may, for example, be a plasma source, a synchrotron-based radiation source or a free electron laser (FEL). The illumination radiation 116 emanating from the radiation source 103 is focused by a collector 117 and propagates through an intermediate focus in an intermediate focal plane 118 into the illumination optical unit 104. The illumination optical unit 104 comprises a deflection mirror 119 and, arranged downstream thereof in the beam path, a first facet mirror 120 (having schematically indicated facets 121) and a second facet mirror 122 (having schematically indicated facets 123).

The projection lens 110 comprises a plurality of mirrors Mi (i=1, 2, . . . ), which are consecutively numbered according to their arrangement in the beam path of the projection exposure apparatus 101. In the example illustrated in FIG. 1, the projection lens 110 comprises six mirrors M1 to M6. Alternatives with four, eight, ten, twelve or a different number of mirrors Mi are also possible. The penultimate mirror M5 and the last mirror M6 each have a through-opening for the illumination radiation 116. The projection lens 110 is a doubly obscured optical unit. The projection lens 110 has an image-side numerical aperture that is greater than 0.5 and may also be greater than 0.6 and may be for example 0.7 or 0.75.

During operation of the microlithographic projection exposure apparatus 101, the electromagnetic radiation incident on the optical effective surface of the mirrors is partly absorbed and, as explained in the introduction, results in heating and an associated thermal expansion or deformation, which can in turn result in an impairment of the imaging properties of the optical system.

The concept according to the disclosure for heating a mirror can be applied to any desired mirror of the microlithographic projection exposure apparatus 101 from FIG. 1. This can be effected to avoid or compensate thermally induced deformations of the mirror in question itself (for example to compensate a spatial distribution of the zero-crossing temperature) or to provide an additional degree of freedom in terms of the setting of the wavefront properties of the entire optical system, that is to say without or with a corrective action being achieved by the mirror in question.

The disclosure then for example includes the concept of realizing, proceeding from the use of an electrical heating device for heating a mirror, comparatively smoother gradients in the heating profile that is ultimately set, by avoiding undesired sharp transitions or edges between different heating zones. To this end, embodiments in which the realization of such a comparatively smooth gradient is effected in different ways are described below.

The heating device has a plurality of heating segments to which electrical current can be applied to generate heat. According to a quantitative criterion for the comparatively smooth gradient, set according to the disclosure, in the deformation profile of the optical effective surface which is ultimately set by the heating segments, this deformation profile is settable as a continuous thermally induced deformation profile with a deformation amplitude of at least 1λ in such a way that the integral of the Fourier analysis over at least one decadic spatial wavelength range is less than 10 mλ.

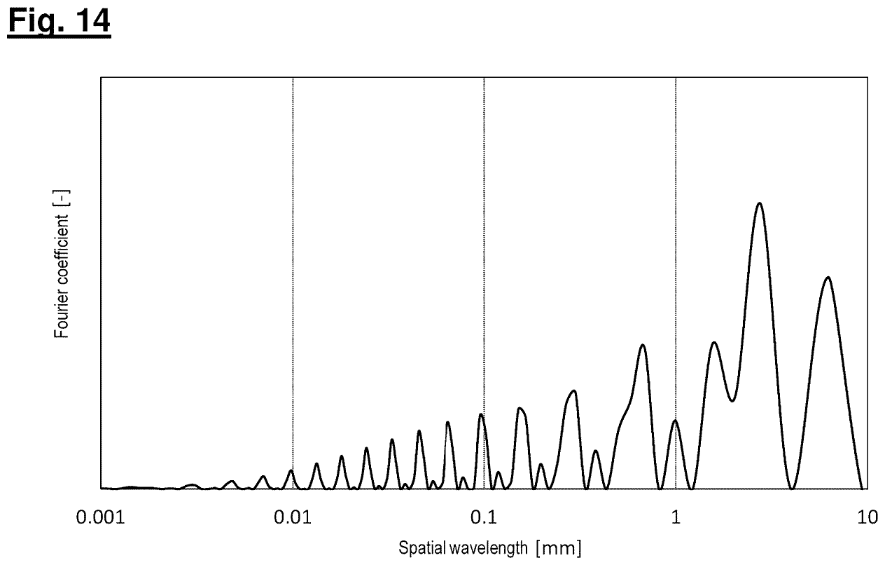

FIG. 14 shows, for illustration for an arbitrary surface structure, a Fourier analysis of the deformation profile in a logarithmic plot of the spatial wavelength axis, the spatial wavelength range from 0.001 mm to 10 mm being illustrated. For an operating wavelength of λ=13.5 nm, the above-mentioned quantitative criterion means that, for the integral of the Fourier analysis for example over the spatial wavelength range from 0.01 mm to 0.1 mm, a value of less than 10 mλ, i.e. a value of less than 0.01*13.5 nm=135 pm is achieved. The deformation profile thus has a comparatively low waviness in this spatial wavelength range.

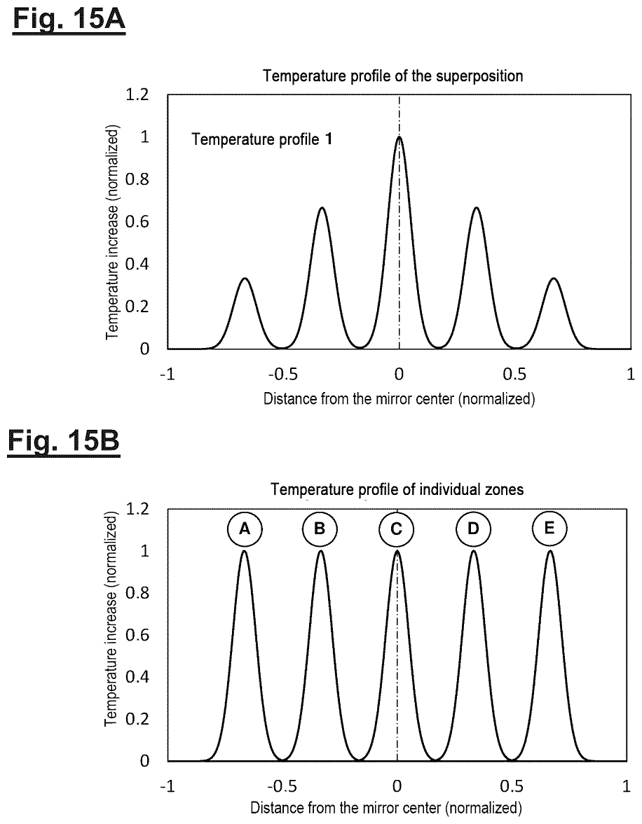

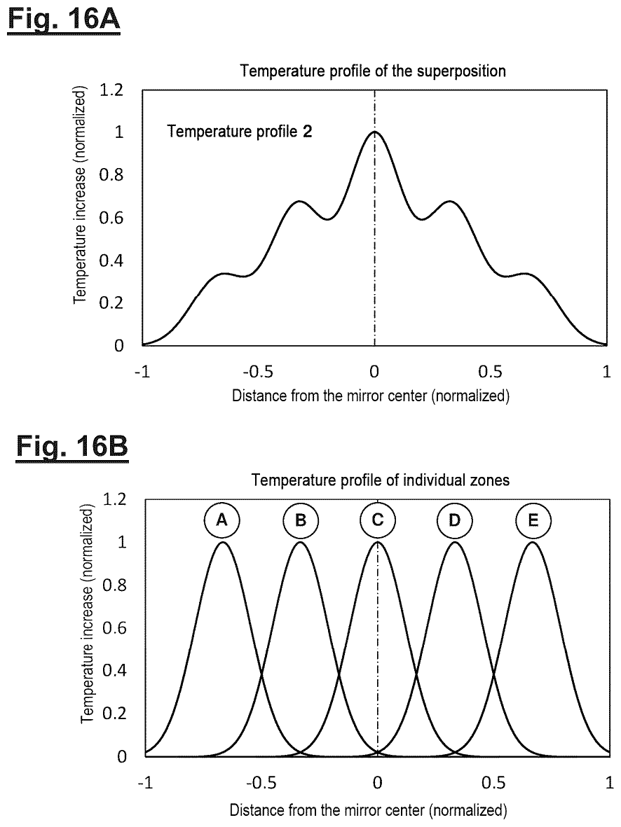

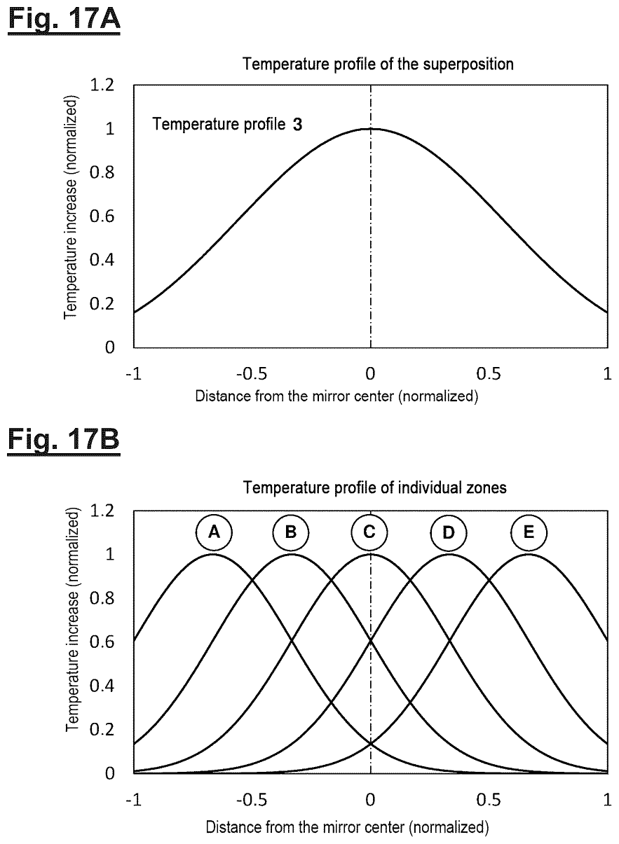

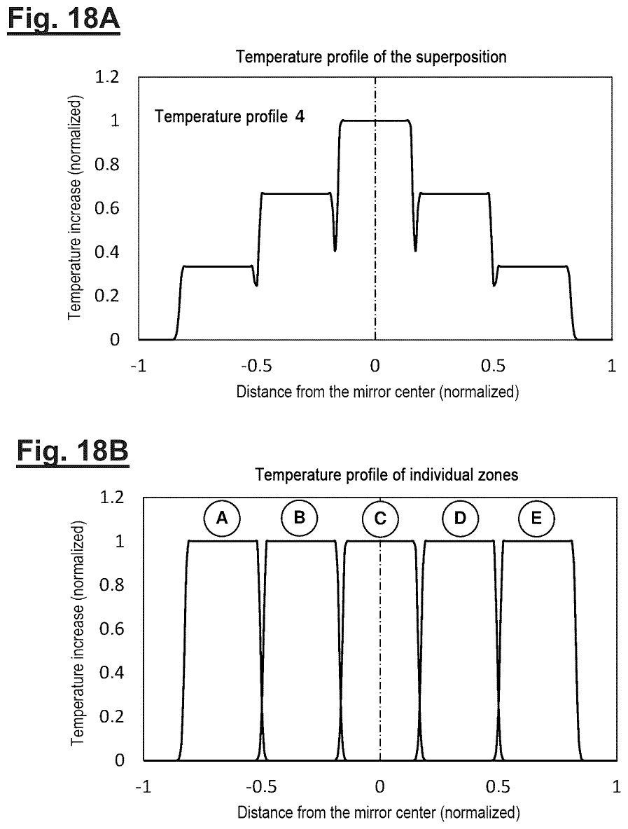

For achieving the smoothest possible temperature profile, both the shape of the temperature profiles generated by the individual heating segments and the overlap thereof are relevant. FIGS. 15A-15B, FIGS. 16A-16B, FIGS. 17A-17B and FIGS. 18A-18B schematically show four different temperature profile types (referred to in FIGS. 15A-18A as “temperature profile 1” to “temperature profile 4”) with, by way of example, five temperature profiles of the individual heating segments, which are referred to in FIGS. 15B-18B as “A”, corresponding to the temperature profile of the heating segment A, to “E”, corresponding to the temperature profile of the heating segment E. The (normalized) superposition of the heating profiles was calculated as 1*T_{A}+2*T_{B}+3*T_{C}+2*T_{D}+1*T_{E}. In the case of “temperature profile 1”, a pronounced waviness of the superposition of the temperatures can be seen. The waviness is reduced in the case of “temperature profile 2” as a result of the greater overlap between the temperature profiles of the individual heating segments “A”-“E”. Owing to the sufficiently great overlap, waviness of the superposition is no longer visible in “temperature profile 3”. “Temperature profile 4” corresponds to a superposition of top hat-like temperature profiles and has a pronounced stepped appearance, which can also be interpreted as waviness.

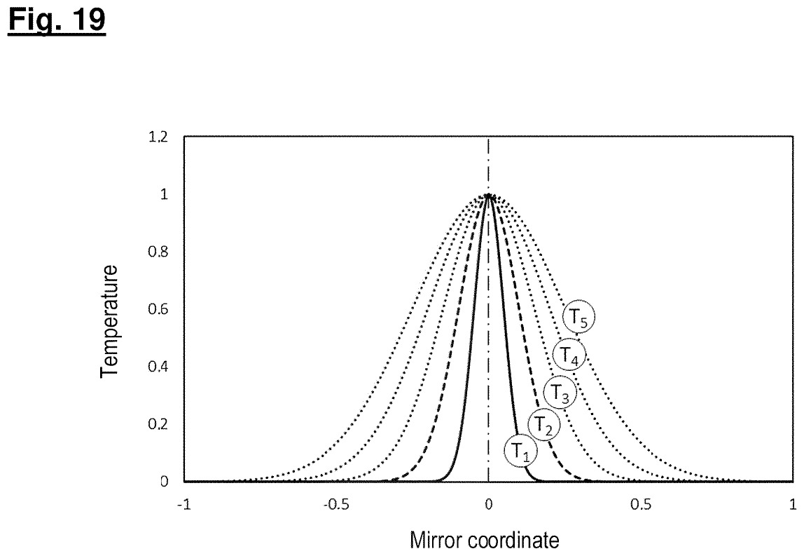

The overlapping of the temperature profiles of adjacent heating segments is promoted by the lateral heat conduction present toward the respectively adjacent heating segments. FIG. 19 is intended to illustrate this. If a temperature is applied in the center of a body, the thermal energy runs away into regions of low temperature, as a result of which these regions are heated and the temperature profile overall becomes wider. At the time t₁, a surface temperature T₁ prevails on the body, at a later time t₂, a surface temperature T₂, etc.

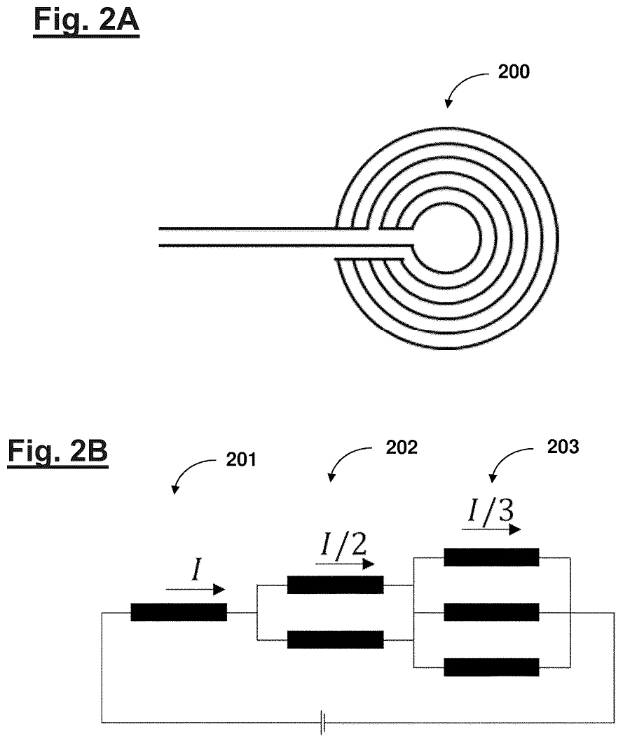

FIG. 2A shows a schematic illustration for explaining a possible refinement of a heating device according to the disclosure, a corresponding equivalent circuit diagram being illustrated in FIG. 2B to explain the functioning. According to FIG. 2A, the heating device according to the disclosure comprises, in a first embodiment, electrical conductor tracks in a branched arrangement, wherein in the present case—but without the disclosure being restricted thereto—a spiral-shaped arrangement is formed. Specifically, here a conductor track running from the spiral interior divides radially outwardly according to the spiral-shaped course first into two conductor tracks and then into three conductor tracks, which, assuming a constant cross section of the conductor tracks according to the equivalent circuit diagram of FIG. 2B, is associated with a reduction in the electrical currents flowing through the respective conductor tracks first to half and then to a third. Also assuming a constant cross section of the conductor tracks, the specific heat capacity per line length is proportional to the square of the current, with the result that the resultant heating capacity from radially inside to radially outside decreases to a third.

The refinement described above then not only results in a local variation of the heat distribution introduced into the respective optical element to be heated (e.g. an EUV mirror), but also can be desirable, for instance in comparison to conventional sector heating with heating zones which are sharply demarcated from one another, that undesired stepped profiles in the thermalization or the deformation profile that is ultimately thermally induced are avoided.

As described below, in order to smooth the heating or deformation profile, it is additionally or alternatively also possible to realize a mutual partial overlap of heating zones generated by different heating segments, for which corresponding heating segments may be present in different planes or in an interleaved arrangement (formed in one and the same plane).

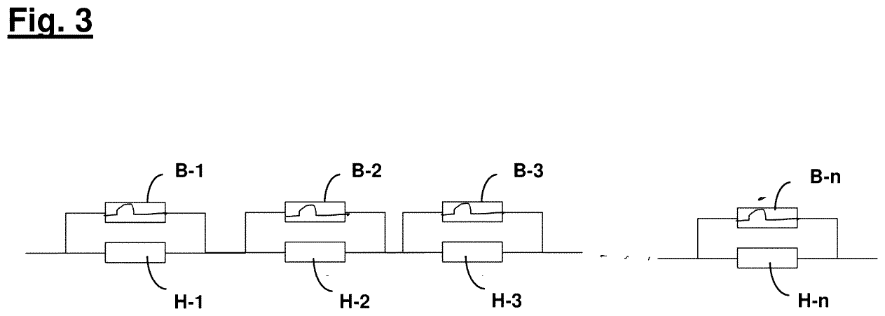

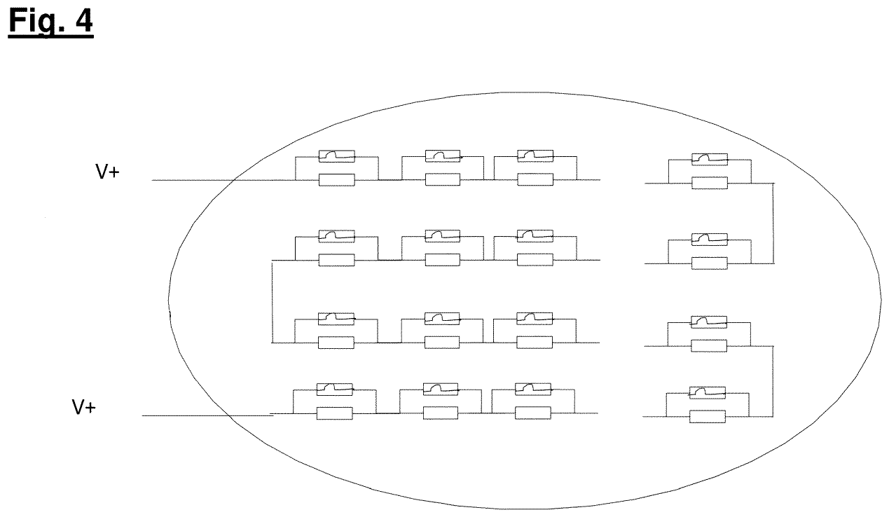

FIG. 3 and FIG. 4 show schematic illustrations of refinements of the actuation of different heating segments of a heating device according to the disclosure, the wiring effort associated with this actuation being limited in each case. According to this concept, the heating segments in question are selectively actuated by way of different frequencies of the actuation signal, which according to FIG. 3 is effected using band-stop filters B-1, B-2, . . . assigned to the individual heating segments (with heating resistors H-1, H-2, . . . ). The actuation signals of different frequency can therefore be conducted via one and the same lead, since only the actuation signal with the frequency blocked by the first band-stop filter B-1 flows via the first heating resistor H-1, only the actuation signal with the frequency blocked by the second band-stop filter B-2 flows via the heating resistor H-2, etc. As a result, overall only two leads for the heating device are used, with the result that the number of lines is reduced significantly.

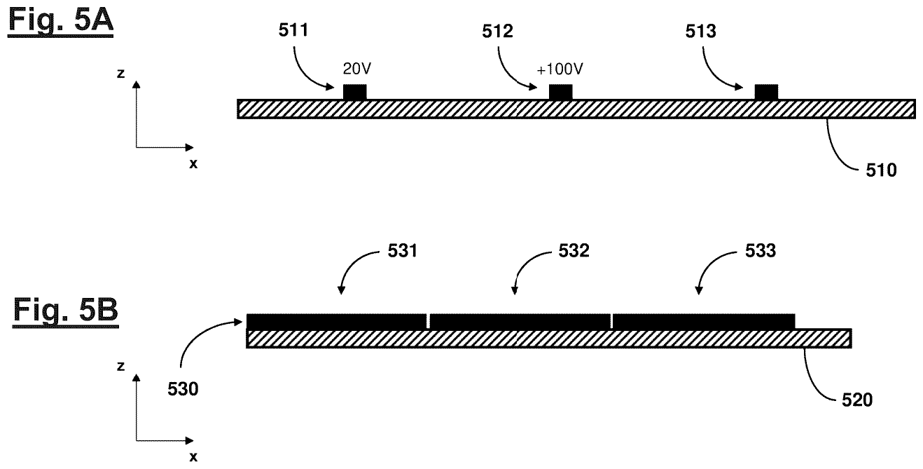

The generation according to the disclosure of a desired heating profile when heating an optical element may, in further embodiments according to FIGS. 5A-5B, also be effected using an electrical mediator layer with comparatively low electrical conductivity. According to FIG. 5A, such a mediator layer is denoted by “510” and electrodes denoted by “511”, “512”, “513”, . . . are used to apply a voltage which is locally variably settable to the mediator layer for the resistive heating. The heating profile which is ultimately set here may additionally be predefined by way of the suitable structuring of the electrodes.

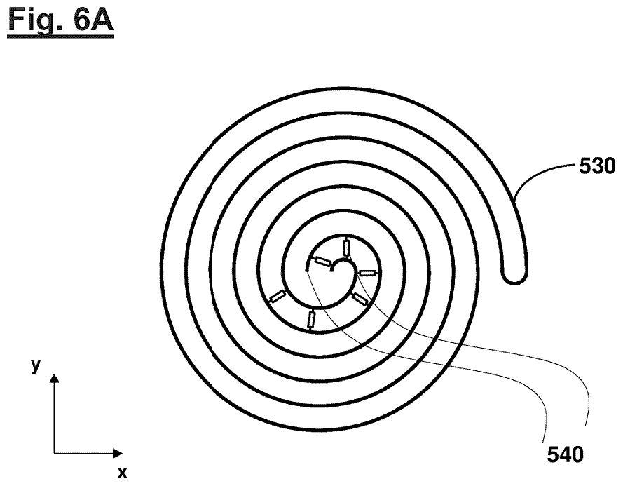

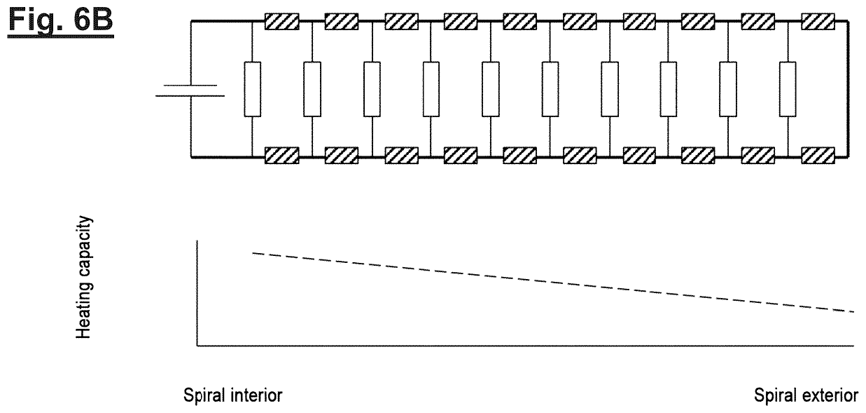

FIG. 5B schematically shows a further exemplary embodiment, wherein a mediator layer 520 of comparatively low electrical conductivity is used in combination with a spiral-shaped conductor track, with the result that—as indicated in section according to FIG. 5B and in plain view according to FIG. 6A—the mediator layer 520 in each case enables a partial short-circuit between the radially adjacent portions 531, 532, 533 of the spiral-shaped conductor track 530. In this case, in FIG. 6A, the voltage source for generating the electrical voltage applied to the spiral-shaped conductor track 530 is denoted by “540”. According to the equivalent circuit diagram illustrated in FIG. 6B and the diagram, also shown in FIG. 6B, for the gradient of the heating capacity from the spiral interior to the spiral exterior, as a result of the partial current flow via the mediator layer 520 (which is represented in FIGS. 6A-6B by way of ohmic resistors), the heating capacity which is locally introduced into the respective optical element decreases radially toward the outside. Since the heating profile is influenced both by the course of the conductor track and by the mediator layer, the number of degrees of freedom of design when setting a desired heating profile is increased as a result. The mediator layer 520 may also be embodied in a structured manner in order to influence the heating profile.

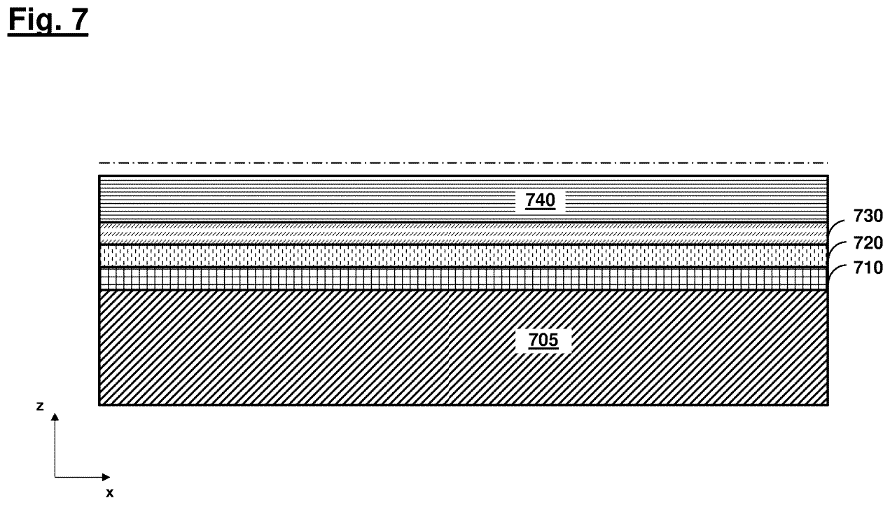

FIG. 7 shows a schematic illustration of a further possible embodiment. In order to heat an optical element in the form of a mirror with a mirror substrate 705 and a reflection layer system 740, use is made here of a heating layer 720 of comparatively high specific electrical resistance, this heating layer 720 being arranged between a first electrode layer 730, located on its side facing the reflection layer stack 740, and a second electrode layer 710, located on its side facing the mirror substrate 705. The electrode layers 710, 730 may be designed in a structured manner suitably for generating a desired heating profile. In contrast to the embodiments described above, according to FIG. 7, the electrical current flow for generating the heating profile occurs in the z-direction in relation to the depicted coordinate system. The electrical resistance of the heating layer 720 is higher than the electrical resistance of the leads or the electrode layers 710, 730 such as at least by a factor of 100, for example by at least a factor of 1000, for example by at least a factor of 10 000.

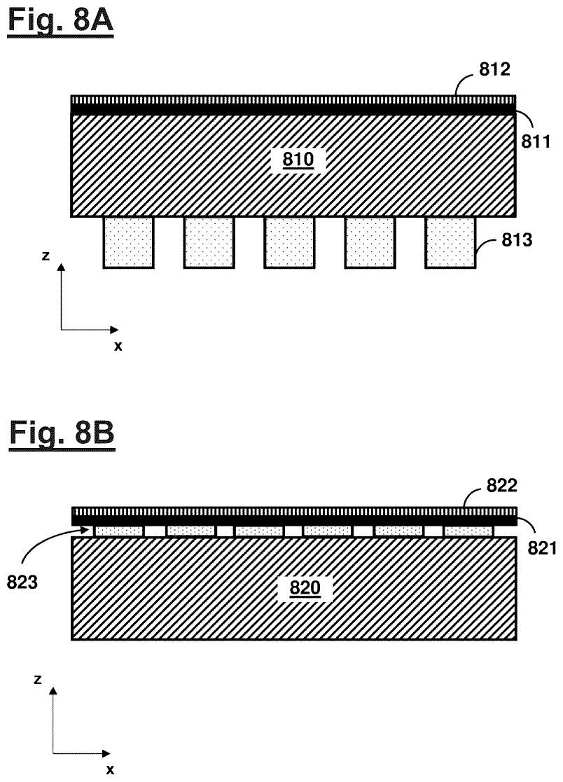

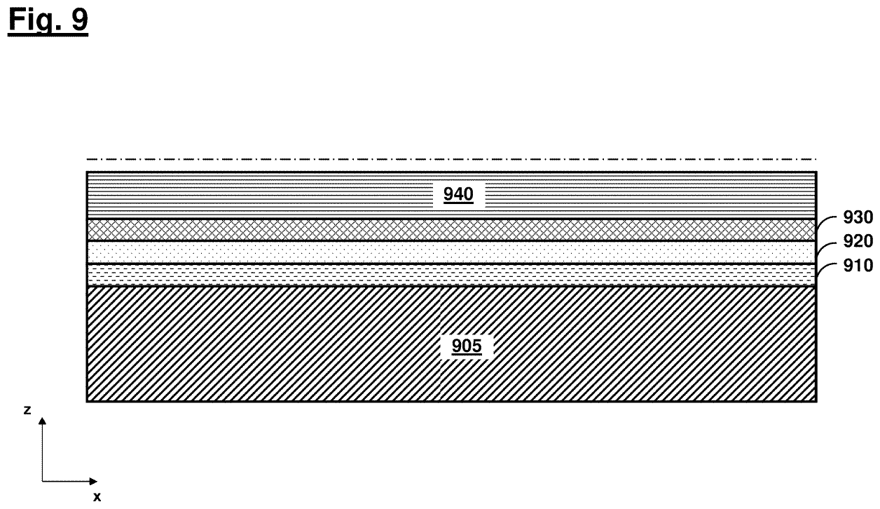

In further embodiments, a locally selective or controllable heat input may also be realized by virtue of alternating magnetic fields being used to induce electrical eddy currents in at least one electrically conducting inductive layer. FIGS. 8A-8B show schematic illustrations of corresponding embodiments. In FIGS. 8A-8B, an inductive layer is denoted by “812” and “822”, respectively, an insulating layer is denoted by “811” and “821”, respectively, and the mirror substrate is denoted by “810” and “820”, respectively. In the shown embodiments (but without the disclosure being restricted thereto), use is made of a coil array 813 and 823, respectively, for providing a plurality of effective heat sources and generating a desired temperature distribution. Furthermore, the formation of eddy currents and thus the heat input may also be influenced by suitable configuration of electrically conducting regions within the inductive layer 812 and 822, respectively. In the application of the principle to a mirror as illustrated in FIGS. 8A-8B, the coils or the coil array may be arranged on the rear side of the mirror (cf. FIG. 8A) or within the layer structure of the mirror or near the optical effective surface of the mirror (cf. FIG. 8B, in which the optical effective surface itself is not illustrated).

In the embodiments described above, use is made of the principle according to which, as a result of eddy current losses occurring at the respective location of the current flow, heat is introduced into the electrically conductive material of the inductive layer, which can be used to deform the optical element or the optical effective surface thereof. Since the penetration depth of such eddy currents is dependent on the frequency of the alternating magnetic field, the location of the respective heat input or the distance thereof from the optical effective surface can be controlled by way of the suitable selection of the frequency of the alternating magnetic field. Here, it is alternatively possible for an electrically conducting, inductive layer of sufficient thickness or a plurality of discrete inductive layers to be provided.

In the realization according to the disclosure of a spatially resolved heat input or the generation of a respective suitable heating profile which varies locally, it is furthermore also possible here to make use of the fact that the spatial spread of the induced eddy currents parallel to the optical effective surface is also frequency-dependent, since in the case of comparatively high frequencies the eddy currents are concentrated closer in the direction of the coil and thus a focused heat input is produced. Furthermore, the shape of the eddy current formation can be manipulated by way of the shape of the coils used to generate the alternating magnetic fields and also through use of suitable ferromagnetic materials (such as iron or ferrite), which increase the magnetic flux density owing to their high permeability. It is furthermore also possible to provide in a targeted manner electrically conductive regions in which eddy current formation is possible. When using ferroelectric materials, it is also possible to utilize the saturation property thereof by application of a static magnetic field for field shaping or eddy current formation (in the sense of a ferromagnetic inductive layer).

Furthermore, for the heat input according to the disclosure, it is also possible to use a ferromagnetic layer (utilizing the magnetic reversal losses occurring in ferromagnetic materials). Furthermore, as an alternative to an array of coils, it is also possible for a scanning operation to be realized through use of one or more displaceable coils. In this case, the magnetic fields generated by multiple coils may also be used to bring a ferromagnetic layer to saturation everywhere apart from a field-free point or region, this field-free region then generating heat upon magnetic reversal, with the result that a scanning heat source can be realized through displacement of this field-free region.

The coils used to generate the magnetic field may be formed in any desired manner (e.g. by a coating process or by winding of a wire). Furthermore, both the position of the coils and the position of the conducting or inductive layer may be optimized in a manner dependent on installation space either for maximally efficient heating or minimal influencing of further components in the optical system.

In further embodiments, the heating according to the disclosure of an optical element or mirror may be effected by way of heating wires or conductor tracks, which are able to be realized by coating and structuring processes and, when applied to a mirror, may be arranged on the rear side of the mirror. In this case, the coating may be designed such that the conductor tracks have a constant heating per length. Furthermore, variation of the respective cross section of the conductor track or the use of different materials having different specific resistances can also achieve a local variation in the heating capacity.

FIG. 9 shows a schematic illustration for explaining one embodiment in which, in order to smooth the heating or deformation profile, heating segments are realized in different planes or in multiple layers in the form of heating layers 910, 920, 930. In this case, the mirror substrate is denoted by “905” and the reflection layer system is denoted by “940”. As a result of the overlap between the generated heating profiles in different planes, an efficient reduction in the waviness due to superposition of the heating profiles and thus an overall smoother gradient of the resultant temperature profile can be achieved.

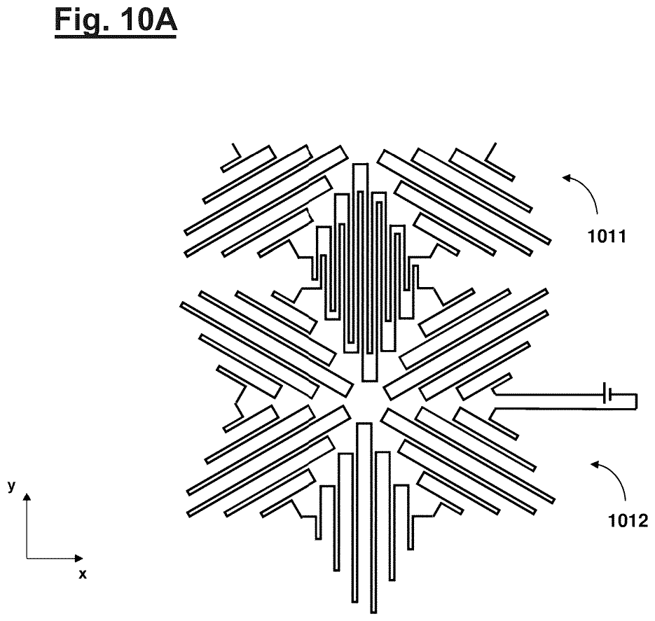

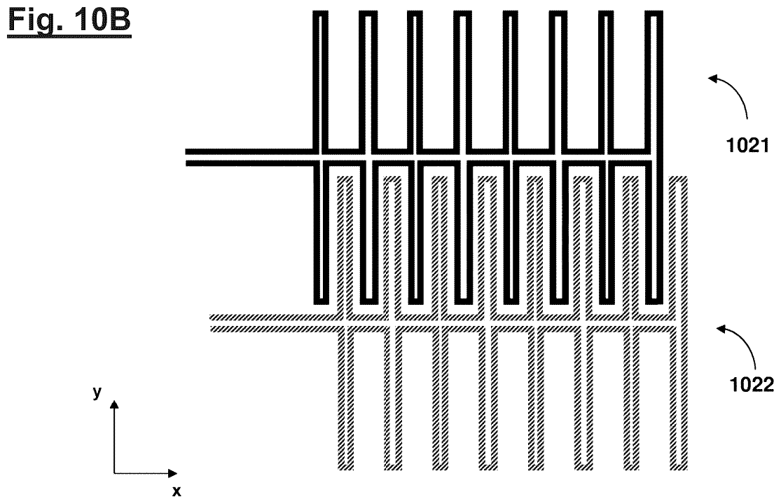

FIGS. 10A-10B show schematic illustrations of possible embodiments of a heating device according to the disclosure, in which-again with the aim of a partial overlap of generated heating zones and an associated smoothing of the heating or deformation profile-different heating segments are provided in an interleaved or interwoven arrangement. In this case, the interwoven or interleaved heating segments for generating mutually overlapping heating zones are located in one and the same plane and are denoted in FIG. 10A by “1011” and “1012” and in FIG. 10B by “1021” and “1022”.

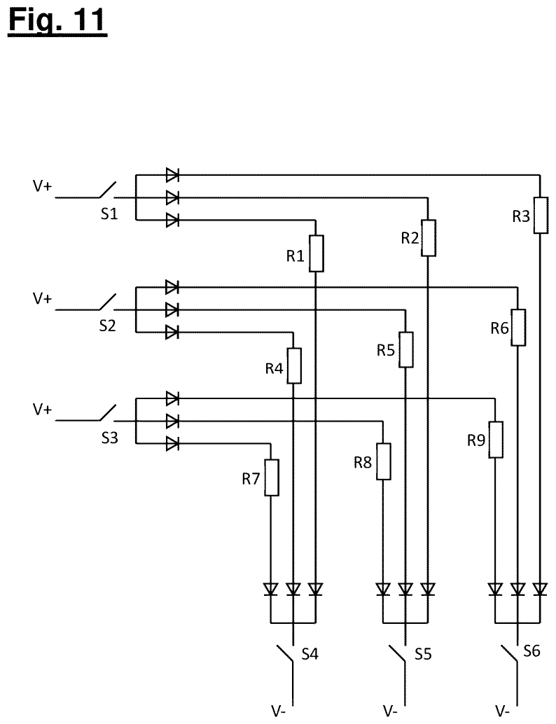

According to FIG. 11, in order to reduce the number of conductor tracks or channels and leads, current paths may also be controlled by way of diodes, in order for individual heating resistors to be switched on or off in a targeted manner. According to FIG. 11, merely by way of example an electrical current flows via the resistor R2 only when switches S1 and S4 are closed. By way of rapid switching (with typical switching times in the range of ms), different channels can be selected in order to achieve spatially selective heating. In the present example, six switches and leads are used for a total of nine heating wires. The circuitry in question can be desirable for example in the case of a large number of heating resistors, twenty switches and leads being sufficient for instance in the case of one hundred heating resistors. The heating resistors may be present at the point of intersection of the respective conductor tracks. In a further embodiment, heating wires may also be spaced apart by a layer of comparatively low conductivity, a flow of electrical current taking place transversely to this layer.

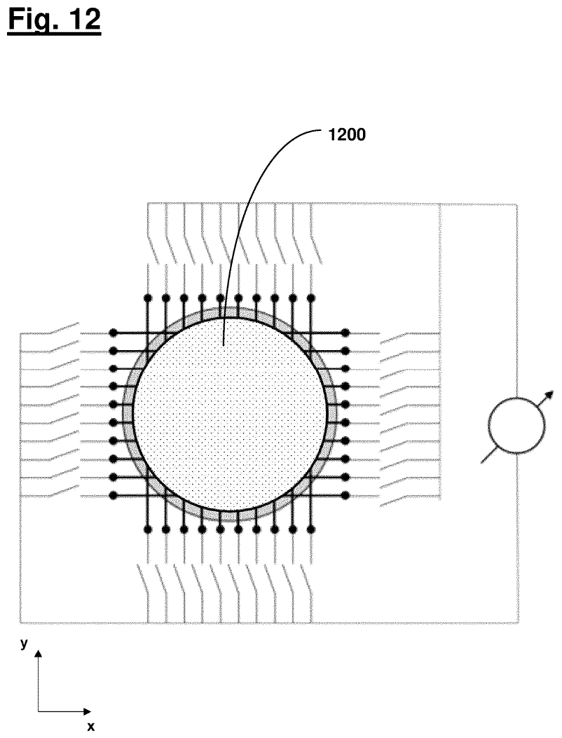

According to FIG. 12, an electrically conductive layer 1200 with external contacts for the heating according to the disclosure may also be used. The generation of magnetic fields provides an additional manipulation possibility for the current path and thus the respective location of the heat input due to the ohmic resistance of the layer.

The aforementioned arrangement of heating wires on the rear side of the mirror can be desirable insofar as parasitic deformation effects via (EUV) light which is incident during operation can be avoided. Furthermore, the mirror substrate may also be produced from different mirror substrate materials, with the aim of maintaining, on the part of the optical effective surface, such as for example utilizing cooling channels, temperatures in the region of the zero-crossing temperature and of setting a targeted deformation on the rear side of the mirror by way of the heating wires.

In further embodiments, heating resistors according to the disclosure may also additionally be used for temperature measurement, wherein the current temperature detected at the location in question can be used as a basis for corresponding temperature control.

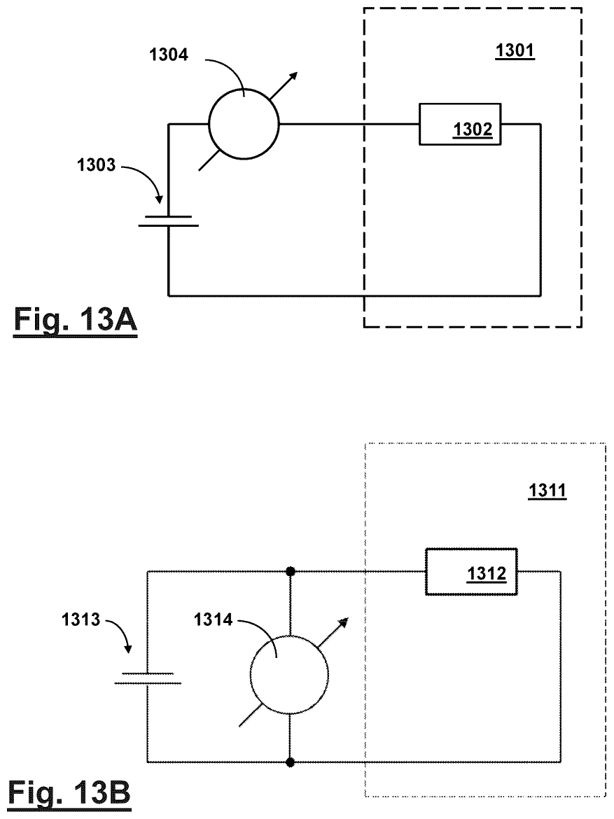

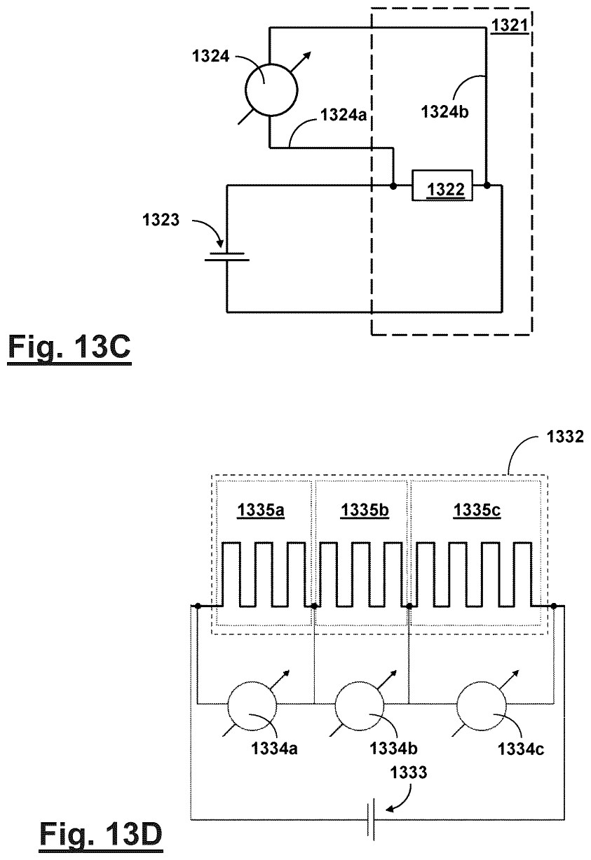

FIGS. 13A-13D show circuits of possible embodiments for explaining this concept. The temperature determination here is based on the fact that the ohmic resistance can be determined from the electrical voltage drop across the respective heating resistor and from the electrical current flowing through the respective heating resistor, wherein knowing the temperature dependency of this ohmic resistance, it is in turn possible to infer an average temperature of the heating resistor in question. Furthermore, the product of the electrical voltage drop across the heating resistor and the electrical current flowing through the heating resistor corresponds to the heating capacity, which can thus also be ascertained and be used as a basis for control or regulation.

FIG. 13A shows a possible embodiment in which a heating resistor 1302 present for heating an optical element or mirror 1301 is operated with an electrical voltage source 1303, and wherein an ammeter 1304 measures the electrical current flowing through the heating resistor 1302. It should be pointed out that here the accuracy of the determination of the ohmic resistance and thus of the temperature is impaired by virtue of the fact that only the voltage drop across the total circuitry (i.e. electrical lines, heating resistor and internal resistor of the ammeter) and not across the heating resistor alone is known.

FIG. 13B shows a further possible embodiment in which a heating resistor 1312 for heating an optical element or mirror 1311 is operated with a current source 1313, the voltage being measured here by way of a voltmeter 1314. Since, here, the voltage drop in the electrical lines cannot be separated from the voltage drop across the heating resistor 1312, the accuracy of the determination of the ohmic resistance and thus of the temperature is also impaired here.

In order to avoid or reduce the aforementioned losses in accuracy, it is possible, according to FIG. 13C (with a heating resistor 1322 operating analogously to FIG. 13B by way of a current source 1323) for the electrical voltage to be tapped by way of two additional voltage measurement lines 1324a, 1324b at two points in the region of the heating resistor 1322 and measured using a voltmeter 1324. In order to achieve the highest possible measurement accuracy, the corresponding voltage taps are preferably realized at the start and end of the conductor track forming the heating resistor 1322 in question (that is to say at the transition from lead to heating segment).

FIG. 13D shows a further possible embodiment in which, in order to achieve a higher spatial resolution of the temperature determination, a plurality of voltage taps are realized within the conductor track forming the respective heating resistor 1332, as a result of which a plurality of temperature measurement regions 1335a, 1335b, 1335c are realized. In this case, the corresponding voltmeters for voltage measurement are denoted by “1334a”, “1334b” and “1334c”.

The temperature measurement described above on the basis of FIGS. 13A-13D may take place in parallel with the respective heating operation. As an alternative, the heating may also be interrupted for the duration of the respective temperature measurement. Here, a defined electrical current is then applied to the respective heating resistor, in order to determine the associated voltage drop.

The embodiments described above may also be combined with direct cooling of the optical element or mirror in question.

Although the disclosure has also been described on the basis of special embodiments, numerous variations and alternative embodiments, e.g. by combining and/or exchanging features of individual embodiments, can be discerned by those skilled in the art. Accordingly, it is understood by those skilled in the art that such variations and alternative embodiments are also comprised by the present disclosure, and the scope of the disclosure is limited only in the sense of the appended claims and their equivalents.

What is claimed is:

1. An optical system having a predefined operating wavelength 2, the optical system comprising:
an optical element which comprising an optical effective surface; and
a heating device configured to heat the optical element,
wherein:
the heating device comprises a plurality of heating segments;
portions of the heating segments engage with each other;
the heating segments are configured to generate heat when an electrical current is applied to the heating segments; and
the heating segments are configured to set a continuous thermally induced deformation profile of the optical effective surface with a deformation amplitude of at least 1λ so that that an integral of a Fourier analysis over at least one decadic spatial wavelength range is less than 10 mλ.

2. The optical system of claim 1, wherein the continuous thermally induced deformation profile of the optical effective surface with the deformation amplitude of at least 1 2 is settable so that the integral of the Fourier analysis over the at least one decadic spatial wavelength range is less than 5 mA.

3. The optical system of claim 1, wherein the at least one decadic spatial wavelength range comprises spatial wavelengths less than 100 micrometers.

4. The optical system of claim 1, wherein the at least one decadic spatial wavelength range comprises spatial wavelengths from 100 micrometers to 1 millimeter.

5. The optical system of claim 1, wherein the at least one decadic spatial wavelength range comprises spatial wavelengths from 1 millimeter (mm) to 10 mm.

6. The optical system of claim 1, wherein the operating wavelength is less than 250 nanometers.

7. The optical system of claim 1, wherein the operating wavelength is less than 30 nanometers.

8. The optical system of claim 1, wherein the heating segments are configured so that when the heating segments generate heat, at least two heating zones generated by different heating segments partially overlap one another.

9. The optical system of claim 1, wherein the heating segments are in at least two planes which are at different distances from the optical effective surface.

10. The optical system of claim 1, wherein the heating segments comprise electrical conductor tracks which: 1) define a branched arrangement; and/or 2) vary in terms of their width, their relative distance from one another or their material.

11. The optical system of claim 1, wherein the heating segments comprise layers or layer segments.

12. The optical system of claim 1, wherein the heating segments are selectively actuatable independently of one another to variably set different thermally induced deformation profiles in the optical element.

13. The optical system of claim 12, wherein the selective actuation of the heating segments comprises transmission of actuation signals of different frequency to different heating segments via a common lead.

14. The optical system of claim 1, wherein the system comprises a control device configured to vary a thermally induced deformation profile generated in the optical element via the heating device depending on an illumination setting set in the optical system.

15. The optical system of claim 1, wherein the optical element comprises a mirror.

16. An apparatus, comprising:
an optical system according to claim 1,
wherein the apparatus is a microlithographic projection exposure apparatus.

17. A method of operating an optical system, the optical system having a predefined operating wavelength λ, the optical system comprising an optical element and a heating device, the optical element comprising an optical effective surface, the heating device comprising a plurality of heating segments, the method comprising:
applying electrical current to the plurality of heating segments to generate heat to set a continuous thermally induced deformation profile of the optical effective surface with a deformation amplitude of at least 1λ in such a way that the integral of the Fourier analysis over at least one decadic spatial wavelength range is less than 10 mλ.

18. The method of claim 17, further comprising varying the thermally induced deformation profile set via the heating segments depending on an illumination setting set in the optical system.

19. The method of claim 17, comprising, when operating the optical system, setting the continuous thermally induced deformation profile top at least partially compensate a deformation of the optical element due electromagnetic radiation impinging on the optical element.

20. The method of claim 17, comprising, when operating the optical system, setting the continuous thermally induced deformation profile to at least partially compensate an optical aberration.
